(19) United States
(12) Patent Application Publication
(10) Pub. No.: US 2007/0069212 A1
(43) Pub. Date: Mar. 29, 2007

(54) FLAT PANEL DISPLAY AND METHOD FOR MANUFACTURING THE SAME

(75) Inventors: Mitsuo SAITOH, Osaka (JP); Hidehiro YOSHIDA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/534,815

(22) Filed: Sep. 25, 2006

(30) Foreign Application Priority Data
Sep. 29, 2005 (JP) 2005/284325

(51) Int. Cl. H01L 29/04

(52) U.S. Cl. 257/59; 438/149

(57) ABSTRACT

The present invention relates to a flat panel display having high picture quality, high flexibility and high flex-resistance. Specifically, the present invention provides a flat panel display having a plurality of pixels arranged in a matrix shape on a substrate, each of the plurality of pixels comprising a thin film transistor having a channel region containing nanowire, nanorod, nanoribbon, or nanotube, and a display element driven by the thin film transistor. Here, an axial direction of the nanowire, nanorod, nanoribbon, or nanotube is in the same direction as the source-drain direction of a channel region and the flat panel display can be bent so as to intersect with the source-drain direction.

### CROSS REFERENCE TO RELATED APPLICATION

This application claims priority based on Japanese Patent Application No. 2005-284325 filed on Sep. 29, 2005. The entire content disclosed in the specification of the aforementioned application is incorporated in the specification of this application.

### BACKGROUND OF THE INVENTION

1. Field of the Invention

The present invention relates to a flat panel display, and more particularly to a flexible flat panel display.

2. Description of the Related Art

In recent years, flat panel display such as organic EL display and liquid crystal display etc. is required for not only thin-model and miniaturization, but also properties (flexibility) capable of being folded or rolled up for easier portability.

On the other hand, high picture quality is also required for flat panel display. In order to attain high picture quality, an active drive scheme incorporating transistor for driving to each pixel is adopted. It is preferable to increase the flexibility of transistor for driving contained for each pixel in order to increase the flexibility of a flat panel display adopting the active drive scheme.

Thin Film Transistor (TFT) is commonly used as transistor for driving and switching of the active drive scheme. Currently, typical thin film transistor is amorphous silicon thin film transistor, etc. On the other hand, the development of organic semiconductor material has been promoted, because organic thin film transistor employing organic semiconductor material has high flexibility. For example, in recent years, pentacene has come to be seen as an organic semiconductor material. However, even for semiconductor employing pentacene, electrical mobility is 1 to 3 cm²/(Vs), and semiconductor of an electrical mobility of 10 cm²/(Vs) or more is desired from the market. Therefore, there is a case where the performance of organic thin film transistor is not sufficient.

Further, organic electroluminescence display constituting thin film transistor having channel region composed of nano-particle as transistor for driving is well-known (Japanese Patent Application Laid-Open No. 2005-244240). It is reported that thin film transistor having channel region composed of nano-particle is capable of being produced under low-temperature conditions so that plastic product as a material with little resistance to heat can be used as a transistor substrate.

Electrical mobility of nano-particle, for example, carbon nanotube and silicon nanowire is compatible to the electrical mobility of a morphous silicon. As a result, thin film transistor having a channel region containing nano-particle is compatible to the capability of amorphous silicon thin film transistor. For example, it is reported that an average mobility of silicon nanowire field effect transistor can be 30 to 560 cm²/(Vs) (NANO LETTERS 2003 Vol. 3, No. 2 pp. 149-152). However, in general, it has been difficult to control the arrangement of nano-particle in channel region.

On the other hand, it is well-known that the wettability of electrolyte to macromolecular film is controlled by applying a potential difference between an electrolyte and a macromolecular film (Polymer 1996 Vol. 37 No. 12, pp. 2465-2470). This is according to a theory referred to as electrowetting.

### SUMMARY OF THE INVENTION

It is therefore an object of the present invention to provide a flat panel display having high picture quality, high flexibility, and high flex-resistance.

The present inventors have discovered that a thin film transistor having a channel region containing nanowire where the axial direction of the nanowire is arranged in the same direction as the source-drain direction is difficult to be damaged even if the transistor is bent so as to intersect with the axial direction of the nanowire (i.e. source-drain direction). Then, the inventors have arrived at the present invention by applying this knowledge to a flexible flat panel display.

Further, the present inventors have discovered that if paste containing nanowire arranged in a predetermined direction is transferred to a substrate from a printing plate using a theory referred to as electrowetting, it is possible to arrange the nanowire on the substrate while maintaining the direction of arrangement. Then, the inventors have arrived at the present invention by applying this knowledge to the forming of channel region of thin film transistor.

Namely, a first aspect of the present invention relates to a flat panel display showing the following:

[1] A flat panel display having a plurality of pixels arranged in a matrix shape on a substrate, wherein:

each of the plurality of pixels comprises a thin film transistor having a channel region containing nanowire, nanorod, nanoribbon or nanotube, and a display element driven by the thin film transistor;

an axial direction of the nanowire, nanorod, nanoribbon, or nanotube is in the same direction as the source-drain direction of the channel region; and

the thin film transistor can be bent so as to intersect with the source-drain direction.

[2] The flat panel display according to [1], wherein the nanowire is silicon nanowire, germanium nanowire, or zinc oxide nanowire.

[3] The flat panel display according to [1], wherein the nanotube is carbon nanotube.

[4] The flat panel display according to any of [1] to [3], wherein the source-drain directions of the channel regions of the thin film transistors contained in the plurality of pixels are arranged respectively in the same direction.

[5] The flat panel display according to any of [1] to [4], wherein:

the thin film transistor comprises an insulating layer on which the channel region is formed, a source electrode and drain electrode connected together by the channel region, and a gate electrode controlling current flowing in the channel; and

the insulating layer is composed of organic insulating material.

[6] The flat panel display according to any of [1] to [5] constituting an organic EL display.

[7] The flat panel display according to any of [1] to [5] constituting a liquid crystal display.

A second aspect of the present invention relates to a method for manufacturing a flat panel display showing the following:

[8] A method for manufacturing the flat panel display according to [1], comprising the steps of:

providing a substrate containing a region to be a channel;

providing a paste applied to a printing plate, containing nanowire, nanorod, nanoribbon or nanotube, wherein the nanowire, nanorod, nanoribbon or nanotube is arranged in a desired direction; and

applying a potential difference between the region to be the channel and the paste that are in close proximity to each other, increasing wettability of the paste and transferring the paste from the printing plate to the region to be the channel, wherein the axial direction of the nanowire, nanorod, nanoribbon or nanotube is arranged in the same direction as the source-drain direction of the channel region.

[9] The manufacturing method according to [8] wherein the nanowire, nanorod, nanoribbon or nanotube contained in the paste applied to the printing plate, is arranged in the desired direction using an electric field.

[10] The manufacturing method according to one of [83 and [9], wherein the region to be the channel is on an organic insulating layer.

[11] The manufacturing method according to any of [8] to [10], wherein:

the printing plate is a relief printing plate; and

hairline is formed in the desired direction on a raised surface of the relief printing plate,

[12] The manufacturing method according to any of [8] to [10], wherein the printing plate is a gravure printing plate.

[13] The manufacturing method according to any of [8] to [10], wherein the printing plate is a blanket to which the paste patterned containing nanowire, nanorod, nanoribbon, or nanotube is transferred.

[14] The manufacturing method according to any of [8] to [10] wherein the paste further comprises organic insulating material.

A third aspect of the present invention relates to a method for manufacturing a thin film transistor showing the following:

[15] A method for manufacturing a thin film transistor having a channel region containing nanowire, nanorod, nanoribbon, or nanotube, wherein an axial direction of the nanowire, nanorod! nanoribbon, or nanotube is in the same direction as a source-drain direction of the channel region, the method comprising the steps of:

providing a substrate containing a region to be a channel;

providing a paste applied to a printing plate, containing nanowire, nanorod, nanoribbon or nanotube, wherein the nanowire, nanorod, nanoribbon or nanotube is arranged in a desired direction; and

applying a potential difference between the region to be the channel and the paste that are in close proximity to each other, increasing wettability of the paste and transferring the paste from the printing plate to the region to be the channel, wherein the axial direction of the nanowire, nanorod, nanoribbon or nanotube is arranged in the same direction as the source-drain direction of the channel region.

The flat panel display of the present invention is provided with thin film transistor having a channel region containing nanowire of high electrical mobility so that high picture quality can be achieved. Further, the flat panel display of the present invention is bendable so as to intersect with the axial direction of nanowire etc. contained in the channel region of thin film transistor (i.e. is bendable so as to intersect with the source-drain direction of the channel region), so that the panel has a higher flexibility, and is more difficult to be damaged due to bending. The flat panel display of the present invention can be applied to, for example, roll screen.

### BRIEF DESCRIPTION OF THE DRAWINGS

FIG. 1 schematically shows a thin film transistor, where: FIG. 1A is a cross-sectional view of a thin film transistor, and FIG. 1B and FIG. 1C are plan views of channel regions of thin film transistors;

FIG. 2 shows an example of a pixel containing a thin film transistor and an organic EL element;

FIG. 3 shows an example of a pixel containing a thin film transistor and a liquid crystal element;

FIG. 4 schematically shows a flat panel display where pixels are arranged in a matrix shape;

FIG. 5 shows an example of an apparatus forming a channel region of a thin film transistor through surface printing, where: FIG. 5A shows the whole of the panel, FIG. 5B shows a section for transferring from a printing plate (plate cylinder) to a substrate in an enlarged manner; FIG. 5C shows a substrate obtained through the printing; FIG. 5D shows the printing plate (plate cylinder) of FIG. 5A; and FIG. 5E shows the surface of a raised section of a printing plate (plate cylinder); and

FIG. 6 shows an example of a panel where a channel region of a thin film transistor is formed using a blanket.

### DETAILED DESCRIPTION OF THE PREFERRED EMBODIMENT

1. Flat Panel Display of the Present Invention.

The flat panel display of the present invention is provided with a plurality of pixels arranged in a matrix shape on a substrate, and is a display panel referred to as an active type, where a thin film transistor for driving is incorporated at each pixel. The number of pixels arranged on the substrate is not particularly limited, and may be decided appropriately according to the desired performance of the display apparatus. An example of a flat panel display includes organic EL display and liquid crystal display.

The flat panel display of the present invention has flexibility and is bendable so that it is preferable that the material of the substrate the pixels are arranged on is a material with flexibility. An example of a material with flexibility may include a plastic material, and an example of a plastic material may include acrylic-resin, polyimide, polycarbonate, polyester, poly(ethylene terephthalate), or poly(ethylene naphthalate), etc.

The pixels arranged on the substrate may contain thin film transistor (TFT) and display element driven by the thin film transistor. It is preferable that the number of thin film transistors driving a display element is two, or four or more. Further, each pixel may also have another thin film transistor other than the thin film transistor driving the display element. An example of another thin film transistor may include a switching thin film transistor, or a thin film transistor contained in a driver for a non-light-emitting region, etc.

The thin film transistors contained in each pixel are not particularly limited, but may contain 1) insulating layer, 2) a channel region arranged on the insulating layer, 3) source electrode and drain electrode mutually connected by the channel region and 4) a gate electrode controlling current flowing in the channel. The gate electrode is preferably arranged in the vicinity of a channel region via the insulating layer.

The thin film transistor may be a top contact type, a bottom contact type, a combination of bottom contact type and top contact type, or another type of transistor. Interconnection is straightforward in the case of a bottom contact type.

An insulating layer contained in a thin film transistor may be a layer composed of inorganic insulating material such as silicon dioxide or silicon nitride, or more preferably, a layer composed of an organic insulating material having higher flexibility. An example of organic insulating material may include polyester resin or phenol resin, etc.

A channel region may be arranged on an insulating layer, and form a semiconductor active layer. More specifically, the channel region may be characterized by including nanowire, nanorod, nanoribbon or nanotube (hereinafter referred to collectively as “nanowire etc.”) and by the axial direction of the nanowire etc. being arranged in the same direction as the source-drain direction. “Axial direction” means “longitudinal direction,” and “source-drain direction” means “direction connecting a source electrode and a drain electrode.”

The axial direction of the nanowire etc. and the source-drain direction may be in the same direction and parallel, but it is not necessary to be parallel in a strict sense, and deviation in inclination is acceptable to a certain extent. For example, deviation of an axial direction of nanowire etc. and a source-drain direction may be less than 45 degrees, and preferably 30 degrees or less.

Further, it is not necessary that the axial direction of the nanowire for all of the thin film transistors is in the same direction as the source-drain direction, and an average value for deviation of the axial directions of nanowires etc. of all of the thin film transistors and the source-drain directions may be less than 45 degrees, and preferably 30 degrees or less.

Nanowire etc. contained in the channel region may be P-type or N-type. An example of nanowire may include silicon nanowire, gallium nitride nanowire, germanium nanowire, zinc oxide nanowire or indium phosphide nanowire, etc. An example of nanoribbon may include cadmium sulfide nanoribbon. An example of nanorod may include zinc oxide nanorod. An example of nanotube may include carbon nanotube.

Of these, nanowire or nanotube is preferable, and silicon nanowire, germanium nanowire, zinc oxide nanowire or carbon nanotube is more preferable. This is because electrical mobility is high, and arrangement in a fixed direction in the insulating layer is straightforward.

One nanowire, or two or more nanowires may be contained in the channel region, but one nanowire is sufficient in electrical mobility. The nanowire etc. contained in the channel may also be covered with a Self Assemble Monolayer (SAM). Further, the surface of the nanowire etc. may be subjected to defect passivation. Defect passivation may be carried out with reference to the documents such as NANO LETTERS 2003 Vol. 3, No. 2 pp. 149-152.

At the channel region, in addition to nanowire etc., insulating material may be contained and the channel region may be film-shaped. The insulating material may also preferably be organic insulating material.

The channel region may be electrically connected by a source electrode and a drain electrode. The source electrode and drain electrode may be formed from conductive metal or conductive polymer. An example of a conductive metal may include molybdenum (Mo), tungsten (W), aluminum (Al), chrome (Cr), titanium (Ti), or an alloy thereof. The source electrode and drain electrode may also be composed of multilayer films of different types of metal.

Contact between source electrode or drain electrode, and nanowire contained in channel region may be improved using thermal annealing. Further, nanowire contained in channel region may also make ohmic contact with source electrode or drain electrode. Ohmic contact may be achieved by, for example, carrying out plasma processing to overlapping between the electrode and the nanowire.

Gate electrode may be arranged so as to be able to control current flowing in a channel region i.e. source-drain current. Preferably, the gate electrode may be arranged on the opposite surface of the insulating layer to the surface where the channel region is arranged, and be arranged in the vicinity of the channel region. The gate electrode may be formed from conductive metal of conductive polymer. An example of a conductive metal may include the same kinds of metal such as the source electrode and the drain electrode.

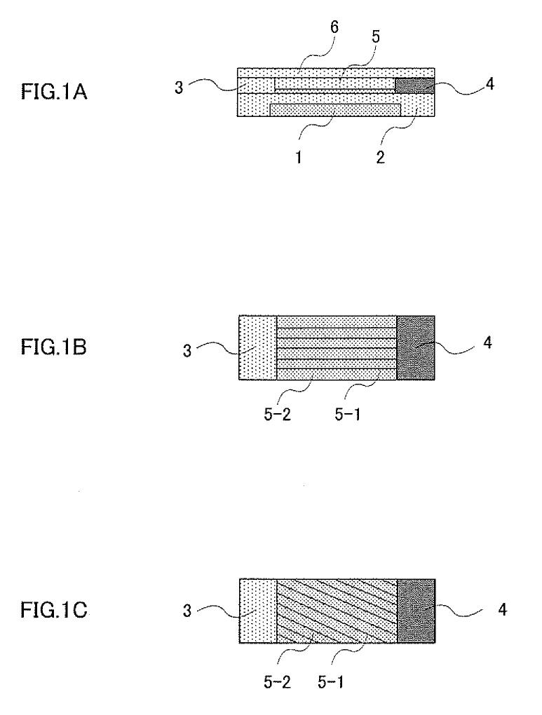

FIG. 1 shows an example of a thin film transistor. Channel region 5, and source electrode 3 and drain electrode 4 connecting the channel region are arranged on insulating film 2, and a sealing film 6 is further formed. On the other hand, gate electrode 1 is arranged via insulating film 2 at channel region 5 (refer to FIG. 1A). Gate electrode 1 may be arranged on the substrate (not shown).

FIG. 1B and FIG. 1C show plan views of channel region 5, source electrode 3 and drain electrode 4 of the thin film transistor shown in FIG. 1A. Channel region 5 contains nanowire etc. 5-1 and organic insulating material 5-2. In FIG. 1B, the axial direction of nanowire etc. 5-1 is arranged to be parallel with the source-drain direction, and in FIG. 1C, the axial direction of nanowire etc. 5-1 is arranged to be inclined to the source-drain direction.

As described above, the flat panel display of the present invention is provided with a plurality of pixels, with each pixel including one or two or more (preferably, two or four or more) thin film transistors. The source-drain directions of the channel regions of the respective thin film transistors may be arranged in the same direction. The same direction means preferably parallel, but it is not necessary to be parallel in a strict sense. By the source-drain directions of the respective thin film transistors being in the same direction, the axial directions of the nanowires etc. contained in the channel regions of the respective thin-film transistors are also arranged in the same direction.

The flat panel display of the present invention has flexibility and is bendable, and it is also desirable to be bent so as to intersect with the axial direction of the nanowire etc. ensuring that channel region is not damaged (for example, ensuring that contact between the nanowire etc. and the source electrode or the drain electrode is maintained). The flat panel display of the present invention is therefore bendable so as to intersect with the source-drain direction of the channel region.

“Being bendable so as to intersect with the source-drain direction” preferably means “being bendable about an axis perpendicular to the source-drain direction,” but it is not necessary that the direction is perpendicular in a strict sense. For example, an angle of deviation from the perpendicular may be preferably less than 45 degrees, and more preferably, 30 degrees or less. Further, it is not necessary to be bent so as to intersect with the source-drain directions of all of the thin film transistors, and it is sufficient to be bent so as to intersect with the average direction of the source-drain direction of all of the thin film transistors.

It is preferable that the nanowire etc. contained in the channel region is forcibly bounded with the source electrode and drain electrode at both ends. On the other hand, it is sufficient to be bonded leniently at the substrate at parts other than both ends. Therefore, even if bending takes place so as to intersect with an axial direction of the nanowire etc. (i.e. in a source-drain direction), a central part in the axial direction of the nanowire etc. can absorb the stress due to bending so that damage due to the bending can be suppressed.

As the stress due to bending is absorbed by parts other than both ends of the nanowire contained in the channel region, it is preferable that insulating material contained in the channel region is organic insulating material rather than inorganic insulating material. It is also preferable that the insulating layer is composed of organic material.

Display element driven by thin film transistor is also contained in the pixel with which the flat panel display of the present invention is provided. Organic EL element is contained if the flat panel display of the present invention is an organic EL display, and liquid crystal element is contained in the case of a liquid crystal display.

An organic EL element has an organic film containing a light-emitting layer sandwiched by an anode and cathode. By then connecting the anode with the drain electrode of the thin film transistor or connecting the cathode with the source electrode of the thin film transistor, the organic EL element is driven by the thin film transistor, and the light-emitting layer emits light. It is then possible to obtain a full color display panel by the organic film patterned with colors.

On the other hand, a liquid crystal element has a liquid crystal film sandwiched by an anode and a cathode. By then connecting the anode with the drain electrode of the thin film transistor or connecting the cathode with the source electrode of the thin film transistor, the liquid crystal element is driven by the thin film transistor, and the arrangement of the liquid crystal molecules is controlled so that the amount of light allowed to pass or the amount of light reflected is adjusted.

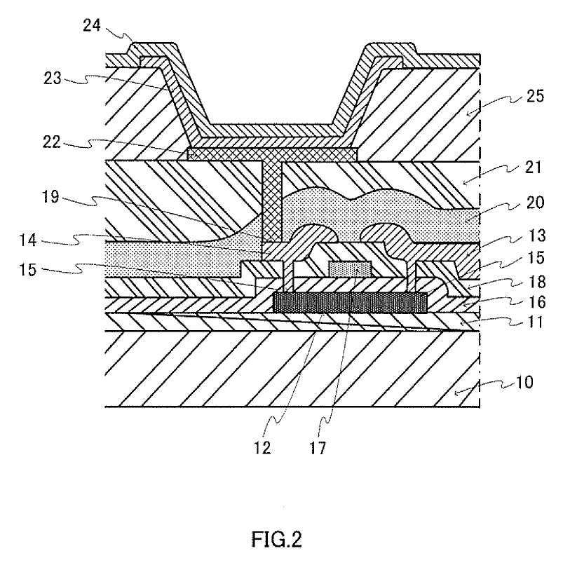

FIG. 2 shows an example of a pixel with which an organic EL display panel of the present invention is provided.

Channel 12 is provided on buffer layer 11 formed on substrate 10. Channel 12 is covered with insulating layer 16 excluding contact holes 15 that are contact portions of source and drain electrodes 13 and 14. Gate electrode 17 is then arranged on channel 12 via insulating layer 16. Gate electrode 17 is covered with gate insulating film 18. Source and drain electrodes 13 and 14 are arranged so as to cover gate insulating film 18, and source and drain electrodes 13 and 14 make contact with channel 12 via contact holes 15. In this way, the thin film transistor is configured.

Further, the whole of the thin film transistor excluding via hole 19 (part of the source or drain electrode 13 or 14) is then covered with passivation film 20, and passivation film 20 is then covered with flattening film 21. Pixel electrode 22 contacting with via hole 19 is arranged on flattening film 21, organic film 23 containing a light-emitting layer is arranged on pixel electrode 22, on which electrode 24 is arranged. These are defined by pixel defining film 25. In this way, an organic EL element is configured.

As described above, nanowire, nanorod, nanoribbon, or nanotube is contained at channel 12, and it's axial direction is aligned with the direction (source-drain direction) connecting the source and drain electrodes 13 and 14.

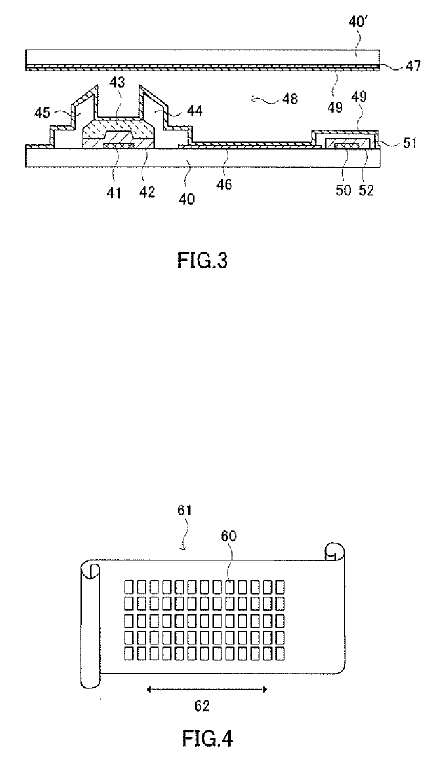

FIG. 3 shows an example of a pixel with witch a liquid crystal display panel of the present invention is provided.

A thin film transistor comprised of gate electrode 41, gate insulating film 42, channel 43, drain electrode 44 and source electrode 45 is formed at substrate 40. On the other side, a liquid crystal element comprised of pixel electrode 46 connecting with the drain electrode 44, transparent electrode 47 provided at substrate 40′ arranged facing substrate 40, and liquid crystal layer 48 sandwiched between pixel electrode 46 and transparent electrode 47 is formed. It is preferable to provide orientation film 49 for appropriately orienting liquid crystal molecules of liquid crystal layer 48. Furthermore, it is also possible to arrange storage capacitor electrodes 50 and 51 and organic insulating thin film 52 at substrate 40 and form a storage capacitor.

As described above, nanowire, nanorod, nanoribbon, or nanotube is contained at channel 43, and it's axial direction is aligned with the direction (source-drain direction) connecting source electrode 45 and drain electrode 44.

FIG. 4 shows flat panel display 61 with a plurality of pixels 60 arranged in a matrix shape, and the source-drain directions of the channel regions of the thin film transistors contained at each pixel are arranged in direction 62 of an arrow Flat panel display 61 shown in FIG. 4 is bent as shown in the drawing, and can be used as a roll screen, etc.

2. Method of Manufacturing a Flat Panel Display of the Present Invention.

Other than the axial direction of nanowire etc. contained in the channel region of thin film transistor being arranged in the same direction as the source-drain direction, the flat panel display of the present invention is manufactured by applying manufacturing methods of the related art appropriately. In the following, means for arranging nanowire etc. in the desired direction will be described, but the present invention is not limited to these means.

The method for manufacturing a flat panel display of the present invention comprises the following steps.

Step a: providing a substrate containing a region to be a channel.

Step b: providing a paste applied to a printing plate, containing nanowire etc. Here, the nanowire etc. is arranged in the desired direction.

Step c: bringing the paste close to the channel region, applying a potential difference between the channel region and paste that are in close, so as to increase wettability of the paste to the channel region, transfer the paste from the printing plate to the channel region.

It is desirable that the channel region is arranged at the substrate provided in Step a, but it is also preferable that the region to be a channel is formed on an insulating layer (or preferably, organic insulating layer). Source electrode and drain electrode may be arranged on the substrate before transferring the paste, but it is preferable to provide the source electrode and the drain electrode after transferring the paste to make workflow easier.

The nanowire etc. contained in the paste applied to the printing plate in Step b may be made using arbitrary methods or may be a commercial item.

In addition to the nanowire, it is also preferable that organic insulating material and solvent are contained in the paste. It is necessary a certain degree of viscosity to maintain the orientation of the nanowire etc. contained in the paste. On the other hand, in the event that arrangement of nanowire etc. in the paste is controlled with an electrical field, it is preferable for viscosity to be adjusted so as to control orientation of the nanowire etc. with the electrical field. For example, the viscosity of the paste may be 50 to 20000 cps (normal temperature). Viscosity can be measured using a rotary viscometer.

Nanowire etc. in the paste applied to the printing plate may be controlled to be in the desired direction after being applied to the printing plate or may be controlled to be in the desired direction before being applied to the printing plate. Means for controlling the direction of the nanowire etc. are not particularly limited, and may be achieved, for example, by placing in an electric field so as to control the axial direction to the direction of the electric field.

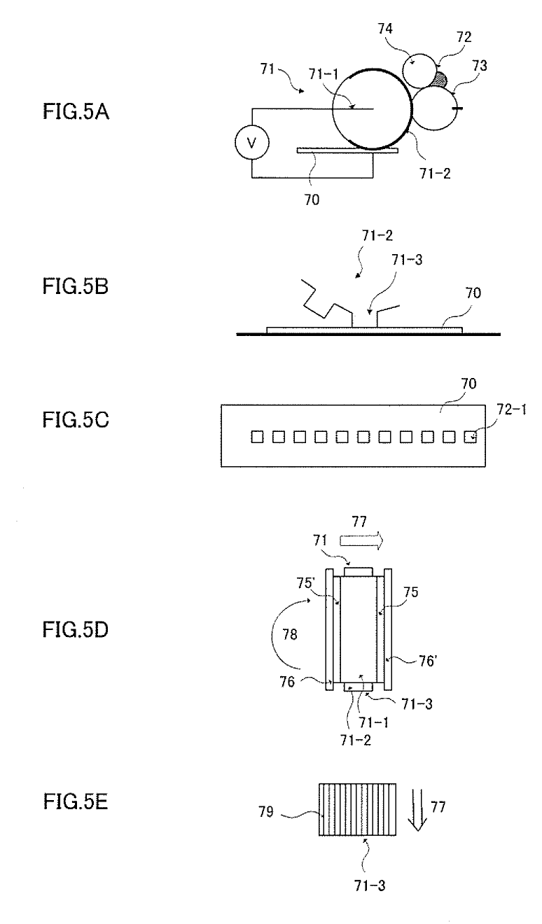

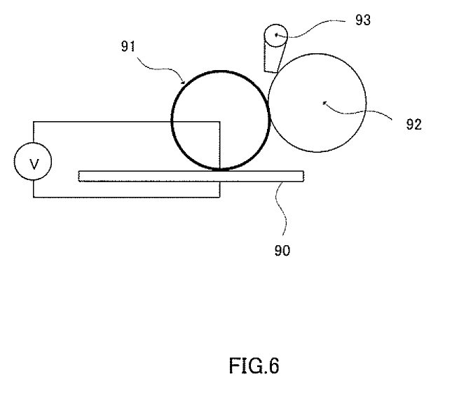

Examples of the printing plate may include “relief printing plate” and “photogravure printing plate,” from which the paste may be directly transferred to the substrate. Further, an example of a printing plate may include, for example, a “blanket” that is an intermediate transfer medium, with patterned paste being transferred from relief printing plate or gravure printing plate etc to the blanket. A procedure using each printing plate will be described with reference to the following drawings (FIG. 5 and FIG. 6).

In order to apply a potential to the paste in Step c, a pair of electrodes may be provided at the printing plate to which paste is applied and the rear side of the substrate the paste is to be transferred to and then a potential difference may be applied. The paste to which the potential difference is applied has higher wettability so that the paste can be transferred to the substrate easily, and nanowire etc. arranged in the desired direction in step B is arranged on the substrate while maintaining this arrangement state. The theory for increasing wettability by applying a potential difference is referred to as electrowetting and is described in Polymer Vol. 37 No. 12, pp. 2465-2470, 1996, etc. Further, at the time of transferring the paste, it is possible to control patterning of the paste to the substrate by adjusting the distance or contact angle between the printing plate and substrate.

An example of an apparatus for forming a channel region in a method for manufacturing a flat panel display of the present invention is shown in FIG. 5 (relief printing techniques) and FIG. 6(method using a blanket).

FIG. 5A shows an outline of apparatus for transferring paste containing nanowire etc. to a region to be a channel A region to be a channel is present on substrate 70, and a relief printing plate 71 is a printing plate comprised of plate cylinder 71-1 (a roll of copper plate, etc.) and a flexo plate 71-2 having a relief shaped printing surface. Flexo plate 71-2 maybe at part of plate cylinder 71-1, or maybe fixed to plate cylinder 71-1 using a fixing plate. A pair of electrodes is arranged at substrate 70 and plate cylinder 71-1 of relief printing plate 71, and a potential difference can be applied. Further, an anilox 73 for applying paste 72 is arranged at relief printing plate 71, and doctor roll 74 for supplying paste 72 and controlling the thickness of the paste film is arranged at anilox 73. Although not shown in the drawings, electrodes constituting a pair may be arranged at anilox 73 and plate cylinder 71-1 of relief printing plate 71, and a potential difference may be applied.

FIG. 5B shows the state when paste applied to relief printing plate 71 is transferred to substrate 70 at a portion in the vicinity of the substrate 70. The paste is transferred to substrate 70 appropriately when the paste of raised section 71-3 of flexo plate 71-2 is brought close to substrate 70, because wettability of the paste is increased by applying a potential difference. As a result, as shown in FIG. 5C, paste is patterned onto the substrate 70 (72-1: patterned paste).

Nanowire etc. contained in the paste applied to relief printing plate 71 is arranged in a fixed direction. In order to arrange the nanowire etc. in a fixed direction, it is preferable that relief printing plate 71 is sandwiched by conductors 76 and 76′ via insulators 75 and 75′ and then an electric field may be applied. As a result, the axial direction of the nanowire etc. contained in the paste applied to raised section 71-3 of flexo-plate 71-2 of relief printing plate 71 is arranged along the direction of the electric field (direction of arrow 77). The direction of arrow 78 indicates the rotation direction of the plate cylinder.

As shown in FIG. 5E, blemish referred to as hairline 79 may also be formed in the direction of an electrical field (arrow 77) on the printing surface of raised section 71-3 of flexo plate 71-2. The nanowire etc. is caught up in the hairline 79 so that the nanowire etc. becomes easier to be arranged.

Further, when the paste is applied from anilox 73 to relief printing plate 71, it is also possible to increase wettability to the relief printing plate 71 (flexo plate 71-2) by applying a potential difference between anilox 73 and relief printing plate 71 so that the paste is applied easier.

FIG. 5 showed an apparatus for directly transferring the paste from a relief printing plate to a substrate, but a gravure printing plate may also be used instead of the relief printing plate. Also, in this case, the gravure printing plate is sandwiched between conductor and arrangement of the nanowire etc. can be controlled by applying an electric field.

FIG. 6 is an outline view of apparatus for transferring paste to a channel region using a blanket constituting an intermediate transfer medium. The plate to transfer the paste to the blanket that is an intermediate transfer medium may be a relief printing plate, gravure printing plate or other kind of plate, and FIG. 6 shows an example where paste is transferred from a gravure printing plate to a blanket.

A region to be a channel is provided on substrate 90, and the printing surface of blanket 91 is formed of resin. A pair of electrodes is arranged at substrate 90 and blanket 91, and a potential difference can be applied. Further, gravure printing plate 92 for applying a paste is arranged at blanket 91, and the surface of gravure printing plate 92 is shaped according to the desired pattern. Further, doctor blade 93 is arranged to eliminate excess paste on gravure printing plate 92. The paste is patterned according to the shape of the surface of gravure printing plate 92 and the patterned paste is transferred to blanket 91.

As with the apparatus shown in FIG. 5, the paste applied to blanket 91 is brought close to a region to be a channel on substrate 90 and is transferred. At this time, a potential difference is applied between the paste and the channel region, and wettability of the paste to the channel region is increased. As a result, the paste is patterned on substrate 90.

Control of the arrangement of nanowire etc. contained in the paste can be carried out in the paste applied to gravure printing plate 92 or can also be carried out in the paste applied to blanket 91. For example, gravure printing plate 92 or blanket 91 is then subjected to an electric field by being sandwiched by conductors, as with relief printing plate 71 of FIG. 5D.

When the patterned paste at gravure printing plate 92 is transferred to blanket 91, the transfer is promoted by applying a potential difference between the gravure printing plate 92 and blanket 91.

The apparatus shown in FIG. 6 is an apparatus for transferring paste patterned at gravure printing plate 92 to a substrate via blanket 91, but as described above, a relief printing plate may also be used instead of gravure printing plate.

Whether a blanket that is an intermediate transfer medium can not be used (FIG. 5) or can be used (FIG. 6) is decided appropriately according to the material of the printing surface of the relief printing plate or the gravure printing plate and the material of the substrate.

For example, the gravure printing plate is usually made of metal (for example, a metal roll plated with hardened chrome). When the paste is then directly transferred from the gravure printing plate, the substrate may be damaged according to the types of substrate (for example, glass substrate). On the other hand, when the substrate is a flexible sheet etc., the paste may be transferred directly from gravure printing plate 92. Further, a relief printing plate is typically made of a soft resin, and in this case, the paste can be directly transferred to the substrate without using a blanket. Namely, it is preferable to have a function for absorbing errors on either a printing plate or substrate.

The means for arranging the nanowire etc. in the desired direction are not limited to the above means. For example, it is also possible to arrange the nanowire in the source-drain direction by forming lines at the channel region on the substrate, applying the solution including nanowire etc. along these lines, and drying solvent contained in the applied solution. This method may be implemented with reference to Japanese Patent Application Laid-Open No. 2005-244240.

Further, it is also possible to arrange the nanowire along the source-drain direction by providing a film with nanowire etc. arranged in a fixed direction and transferring the nanowire etc. arranged at the film to a channel region. Here, film where the nanowire etc. is arranged in a fixed direction can be obtained by providing nanowire floating in solution, grouping the floating nanowire etc. to one side, adjusting the nanowire in substantially one direction, and adhering the nanowire etc. aligned to one side to a film. This method may also be implemented with reference to Japanese Patent Application Laid-Open No. 2005-244240.

The flat panel display of the present invention is a display apparatus with a high picture quality where nanowire in channel region of thin film transistor for driving is contained therein, and electrical mobility is therefore high. Further, the flat panel display of the present invention is a display apparatus with a high flexibility where the axial direction of the nanowire in the channel region is arranged in the source-drain direction and bendable so as to intersect with this axial direction. This may therefore be provided as a roll screen-type display panel or a portable flat panel display.

What is claimed is:

1. A flat panel display having a plurality of pixels arranged in a matrix shape on a substrate, wherein:
each of the plurality of pixels comprises a thin film transistor having a channel region containing one selected from the group consisting of nanowire, nanorod, nanoribbon and nanotube, and a display element driven by the thin film transistor; and
an axial direction of the one selected from the group consisting of the nanowire, nanorod, nanoribbon and nanotube is in the same direction as the source-drain direction of the channel region; and
the thin film transistor can be bent so as to intersect with a source-drain direction.

2. The flat panel display according to claim 1, wherein the nanowire is one selected from the group consisting of silicon nanowire and germanium nanowire, and zinc oxide nanowire.

3. The flat panel display according to claim 1, wherein the nanotube is carbon nanotube.

4. The flat panel display according to claim 1, wherein the source-drain directions of the channel regions of the thin film transistors contained in the plurality of pixels are arranged respectively in the same direction.

5. The flat panel display according to claim 1, wherein:
the thin film transistor comprises an insulating layer the channel region is formed on, a source electrode and drain electrode connected together by the channel region, and a gate electrode controlling current flowing in the channel; and
the insulating layer is composed of organic insulating material.

6. The flat panel display according to claim 1 constituting an organic EL display.

7. The flat panel display according to claim 1 constituting a liquid crystal display.

8. A method for manufacturing the flat panel display according to claim 1, comprising the steps of:
providing a substrate containing a region to be a channel;
providing a paste applied to a printing plate, containing one selected from the group consisting of nanowire, nanorod, nanoribbon and nanotube, wherein the one selected from the group consisting of nanowire, nanorod, nanoribbon and nanotube is arranged in a desired direction;
applying a potential difference between the region to be the channel and the paste that are in close proximity to each other, increasing wettability of the paste and transferring the paste from the printing plate to the region to be the channel, wherein the axial direction of the one selected from the group consisting of the nanowire, nanorod, nanoribbon and nanotube is arranged in the same direction as the source-drain direction of the channel region.

9. The manufacturing method according to claim 8, wherein the one selected from the group consisting of the nanowire, nanorod, nanoribbon or nanotube contained in the paste applied to the printing plate, is arranged in the desired direction using an electric field.

10. The manufacturing method according to claim 8, wherein the region to be the channel region is on an organic insulating layer.

11. The manufacturing method according to claim 8, wherein:
the printing plate is a relief printing plate; and
hairline is formed in the desired direction on a raised surface of the relief printing plate.

12. The manufacturing method according to claim 8, wherein the printing plate is a gravure printing plate.

13. The manufacturing method according to claim 8, wherein the printing plate is a blanket to which the paste patterned containing the one selected from the group consisting of nanowire, nanorod, nanoribbon and nanotube is transferred.

14. The manufacturing method according to claim 8, wherein the paste further comprises organic insulating material.

15. A method for manufacturing a thin film transistor having a channel region containing one selected from the group consisting of nanowire, nanorod, nanoribbon and nanotube, wherein an axial direction of the one selected from the group consisting of nanowire, nanorod, nanoribbon, and nanotube is in the same direction as a source-drain direction of the channel region, the method comprising the steps of:
providing a substrate containing a region to be a channel;
providing a paste applied to a printing plate, containing the one selected from the group consisting of nanowire, nanorod, nanoribbon and nanotube, wherein the one selected from the group consisting of nanowire, nanorod, nanoribbon and nanotube is arranged in a desired direction; and
applying a potential difference between the region to be the channel and the paste that are in close proximity to each other, increasing wettability of the paste and transferring the paste from the printing plate to the region to be the channel, wherein the axial direction of the one selected from the group consisting of nanowire, nanorod, nanoribbon and nanotube is arranged in the same direction as the source-drain direction of the channel region.
